(19) United States
(12) Patent Application Publication
(10) Pub. No.: US 2008/0035989 A1
(43) Pub. Date: Feb. 14, 2008

(54) Fabricating process and structure of trench power semiconductor device

(75) Inventors: Kou Liang Jaw, Hsinchu (TW); Tsung Chih Yeh, Chiayi (TW); Teck Wei Chen, Taipei (TW); Tien Min Yuan, Taipei (TW); Ming Chuan Chen, Taipei (TW)

Correspondence Address: BACON & THOMAS, PLLC, 625 SLATERS LANE, FOURTH FLOOR, ALEXANDRIA, VA, 22314, US

(73) Assignee: MOSEL VITELIC INC., Hsinchu (TW)

(21) Appl. No.: 11/826,080

(22) Filed: Jul. 12, 2007

(30) Foreign Application Priority Data
Aug. 11, 2006 (TW) 095129704

(51) Int. Cl. H01L 29/78; H01L 21/336

(52) U.S. Cl. 257/330; 438/270; 257/E21.41; 257/E29.262

(57) ABSTRACT

A process for fabricating a trench power semiconductor device is disclosed. A first dielectric layer between the pad oxide layer and the mask oxide layer is formed so as to form a gate with a height higher than the surface of the pad oxide layer after the first dielectric layer is removed. In addition, a sidewall structure is formed at laterals of the gate protruded from the surface of the trench structure. Hence the source structure and the first conductive layer formed at the surface of the gate can be isolated through the sidewall structure. When the trench power semiconductor device is processed at high frequency, the net resistance of the gate can be reduced by the first conductive layer, and thus the electrical properties thereof can be elevated.

### FIELD OF THE INVENTION

The present invention relates to a fabricating process and structure of a trench power semiconductor device, and more particularly to a fabricating process and structure of a trench power semiconductor device with low resistance gate layer.

### BACKGROUND OF THE INVENTION

Trench power semiconductor devices such as trench power metal-oxide-semiconductor field effect transistor (trench power MOSFET) are popularly applied commercially nowadays due to their dual advantages in low on-resistance and fast switching speed. The difference between the trench power MOSFET and the conventional power MOSFET is that the gate conductor of the trench power MOSFET is built within the trench. This particular structure enables to reduce the device area and increase device density without tremendously increases the on-resistance thereof.

Please refer to FIGS. 1(a)-(g), which are schematic diagrams showing the conventional process of trench power MOSFET fabrication. As shown in FIGS. 1(a)-(g), the conventional process for fabricating trench power MOSFET comprises the following steps. First, as shown in FIG. 1(a), a substrate 11 is provided, and an epitaxial layer 12 and a mask oxide layer 13 are formed on the substrate 11 in order. Then a lithography procedure and an etching procedure are performed to remove portion of the mask oxide layer 13 and the epitaxial layer 12 on the substrate 11, and thus the trench structure 14 is formed as shown in FIG. 1(b). The mask oxide layer 13 is removed, and a gate oxide layer 15 is formed on the surface of the epitaxial layer 12 and the inner sidewalls of the trench structure 14. Thereafter, a polysilicon layer 16 is deposited to cover the trench structure 14, as shown in FIG. 1(c). Afterwards, portion of the polysilicon layer 16 is removed to form a gate 17 within the trench structure 14 as shown in FIG. 1(d). Then, a body implantation procedure and a body drive-in procedure are conducted to form a body structure 121 within the epitaxial layer 12 as shown in FIG. 1(e).

Subsequently, as shown in FIG. 1(f), a photoresist layer 18 is formed on the body structure 121, and the source photoresist is defined by photolithography, and a source implantation procedure and a source drive-in procedure are performed to form a source structure 122 as shown in FIG. 1(g). The fabrication of the trench power MOSFET is then completed after deposition of dielectric layer, formation of contact metal layer and other following processes.

Recently, there is a trend to fabricate trench power MOSFET with shallower depth of the trench structure. Shallower depth of the trench structure not only decreases the cross section area of the gate filled in the trench structure, but also raises the resistance of the gate. When the trench power MOSFET is switched at relatively high frequency, elevation of resistance of the gate will cause the increase of the resistive-capacitive time (RC delay time) of the transistor and thus the switch speed of the transistor is influenced and the process speed of the electronic device is limited and cannot be raised. Therefore, when the trench power MOSFET with shallower depth of the trench structure is designed, less gate resistance of the transistor is required, so as to promote the high frequency operation performance of the device.

Titanium silicide layer has been conventionally applied to decrease the net resistance of the gate of the trench power MOSFET. Please refer to FIG. 2, which is a schematic diagram showing partial structure of the trench power MOSFET disclosed in a published patent application of US 2003/0168695A1. As shown in FIG. 2, besides common structures of substrate 11, epitaxial layer 12, body structure 121, source structure 122, gate oxide layer 15, gate 17, and mask layer 21, a titanium silicide layer 22 with low electrical conductivity is further formed on the gate 17 and the mask layer 21 of the trench power MOSFET. Because the resistance of the titanium silicide layer 22 is one fifth of that of the gate 17 and among the gate 17 appears to be parallel connection, the net resistance of the gate 17 can be decreased by forming the titanium silicide layer 22.

The purpose for decreasing the net resistance of the gate 17 of the conventional trench power MOSFET can be achieved by forming additional titanium silicide layer 22 on top of the gate 17; however, the titanium silicide layer 22 could influence the isolation function of the gate oxide layer 15. Especially at the corner of the trench structure, only partial section between the titanium silicide layer 22 and gate 17 and the source structure 122 is isolated via the gate oxide layer 15. Therefore, the electrical voltage applied to the gate 17 might conduct to the source structure 122 directly when the trench power MOSFET is processed at relatively high voltage or high frequency, results in short circuit between the gate 17 and the source structure 122, and thus malfunctions the trench power MOSFET.

Therefore, it is necessary to overcome the above described technological defects by developing a trench power MOSFET structure and a fabricating process thereof for decreasing the net resistance of the gate.

### SUMMARY OF THE INVENTION

An object of the present invention is to provide a trench power semiconductor device and a fabricating process thereof, so as to overcome the shortcomings of poor isolation function of the gate oxide layer of the conventional trench power semiconductor device with the titanium silicide layer and avoid the short-circuit between the gate and the source structure caused by electrical voltage directly conducted to the source structure from the gate.

In accordance with an aspect of the present presentation, the fabricating process of a trench power semiconductor device is provided. The process for fabricating a trench power semiconductor device comprises steps of: (a) providing a substrate, forming a first dielectric layer on the substrate and removing portion of the first dielectric layer and portion of the substrate to form a trench structure; (b) forming a gate oxide layer at inner sidewall of the trench structure; (c) depositing a polysilicon layer to cover the trench structure and removing portion of the polysilicon layer to form a gate within the trench structure; (d) removing the first dielectric layer for allowing portion of the gate to be protruded from the surface of the trench structure and forming a body structure within the substrate; (e) forming a source between the body structure and the gate oxide layer; (f) forming an insulation layer on the gate and the substrate; (g) removing portion of the insulation layer to form a sidewall structure at laterals of the gate protruded from the trench structure and expose portion of the source and the substrate; (h) forming a first conductive layer at the surface of the gate and the exposed portion of the source and the substrate; (i) forming a second dielectric layer on the first conductive layer and the sidewall structure; (j) removing portion of the second dielectric layer, portion of the first conductive layer and portion of the source to define a source structure and forming a contact region; (k) forming a second conductive layer on the contact region and the second dielectric layer; and (l) forming a contact metal layer on the second conductive layer.

In an embodiment, the step (a) further comprises steps of: (a1) providing the substrate and forming a pad oxide layer, the first dielectric layer and a mask oxide layer on the substrate in order; (a2) removing portion of the mask oxide layer to form a trench opening; (a3) removing portion of the first dielectric layer, portion of the pad oxide layer, and portion of the substrate by using the mask oxide layer as a mask to form the trench structure; and (a4) removing the mask oxide layer.

In an embodiment, the first dielectric layer is silicon nitride mask.

In an embodiment, the body structure in the step (d) is formed by a body implantation procedure and a body drive-in procedure, and the step (h) is performed by a salicidation procedure.

In an embodiment, the step (e) further comprises steps of: (e1) forming a photoresist layer on the body structure and defining source photoresist by photolithography; and (e2) performing a source implantation procedure and a source drive-in procedure to form the source.

In an embodiment, the first conductive layer and the second conductive layer are a titanium silicide layer and a titanium nitride layer, respectively.

In an embodiment, the second dielectric layer comprises a borophospho-silicate-glass layer and a non-doped-silicate-glass layer.

In an embodiment, prior then the step (k) further comprises a step of forming a contact plus structure in the body structure and exposing the contact plus structure through the contact region.

In an embodiment, after the step (l) further comprises a step (m) forming a protective layer on the contact metal layer.

In an embodiment, the trench power semiconductor device is a trench power metal-oxide-semiconductor field effect transistor.

In accordance with an aspect of the present presentation, a trench power semiconductor device is provided. The trench power semiconductor device comprises: a substrate; at least a trench structure formed in the substrate; a gate oxide layer formed at inner sidewall of the trench structure; a gate formed within the trench structure and partially protruded from the surface of the trench structure; a sidewall structure formed at laterals of the gate protruded from the surface of the trench structure; a first conductive layer formed at least at the surface of the gate; and a source structure formed within the substrate and nearby the gate oxide layer.

In an embodiment, the gate is a polysilicon layer.

In an embodiment, the first conductive layer is a titanium silicide layer and further formed at portion of the source structure.

In an embodiment, the trench power semiconductor device further comprises a body structure formed within the substrate.

In an embodiment, the trench power semiconductor device further comprises a dielectric layer formed on the first conductive layer and the sidewall structure.

In an embodiment, the trench power semiconductor device further comprises a contact plus structure formed on the substrate.

In an embodiment, the trench power semiconductor device further comprises a second conductive layer being a titanium nitride layer formed on the dielectric layer and the contact plus structure.

In an embodiment, the trench power semiconductor device further comprises a contact metal layer and a protective layer formed on the second conductive layer.

The above objects and advantages of the present invention will become more readily apparent to those ordinarily skilled in the art after reviewing the following detailed description and accompanying drawings, in which:

### BRIEF DESCRIPTION OF THE DRAWINGS

FIGS. 1(a)-(g) are schematic diagrams showing the conventional process for fabricating the trench power MOSFET;

FIG. 2 is a schematic diagram showing partial structure of trench power MOSFET disclosed in a published patent application of US 2003/0168695A1;

FIGS. 3(a)-(m) are schematic diagrams showing the process for fabricating the trench power semiconductor device according to a preferred embodiment of the present invention.

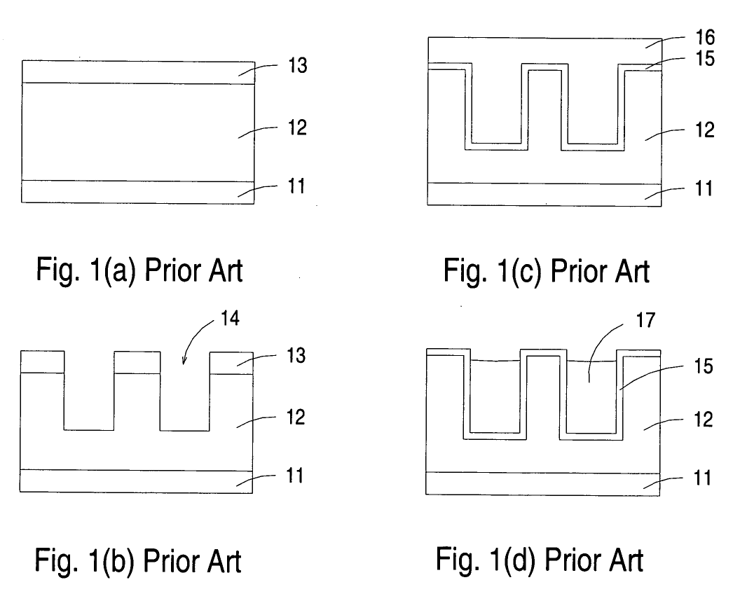

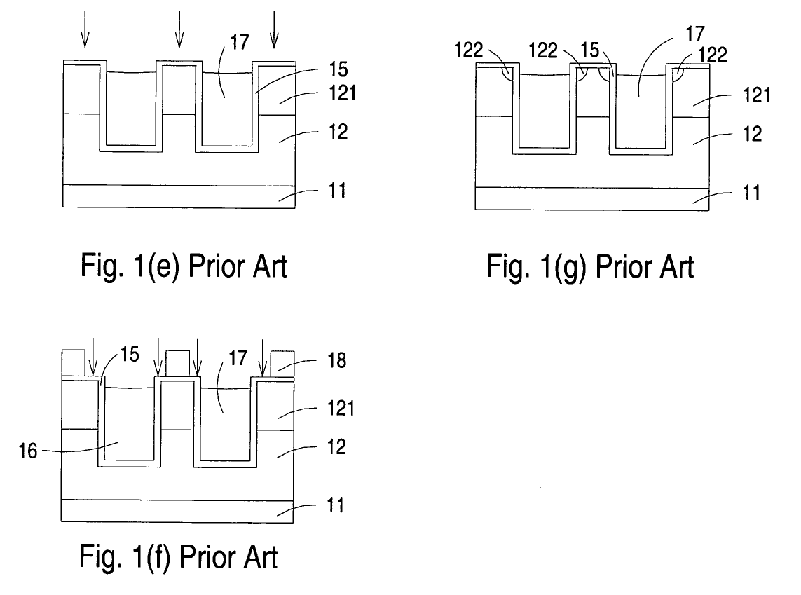

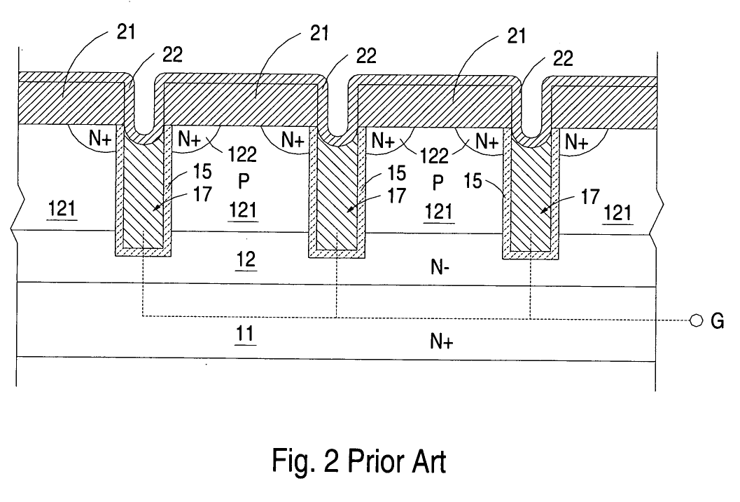

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed.

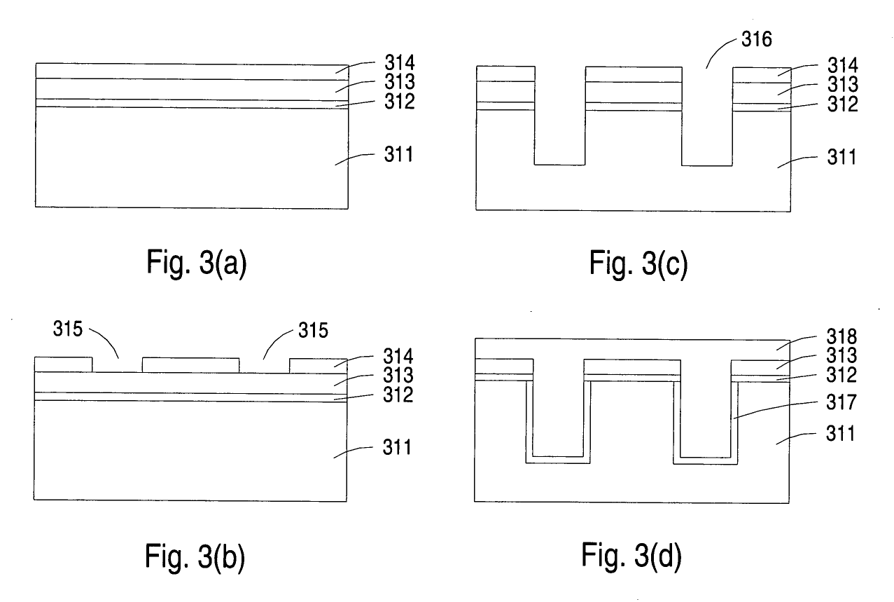

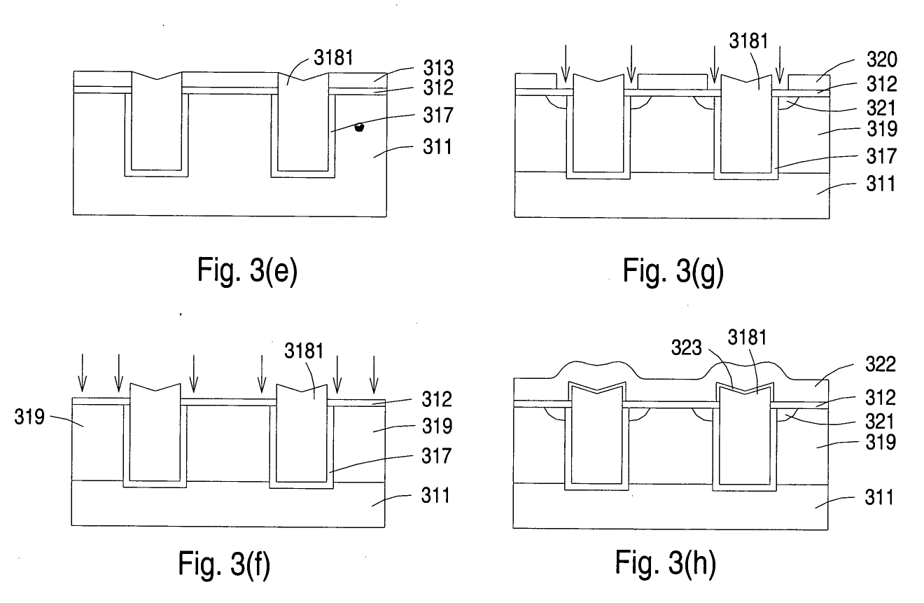

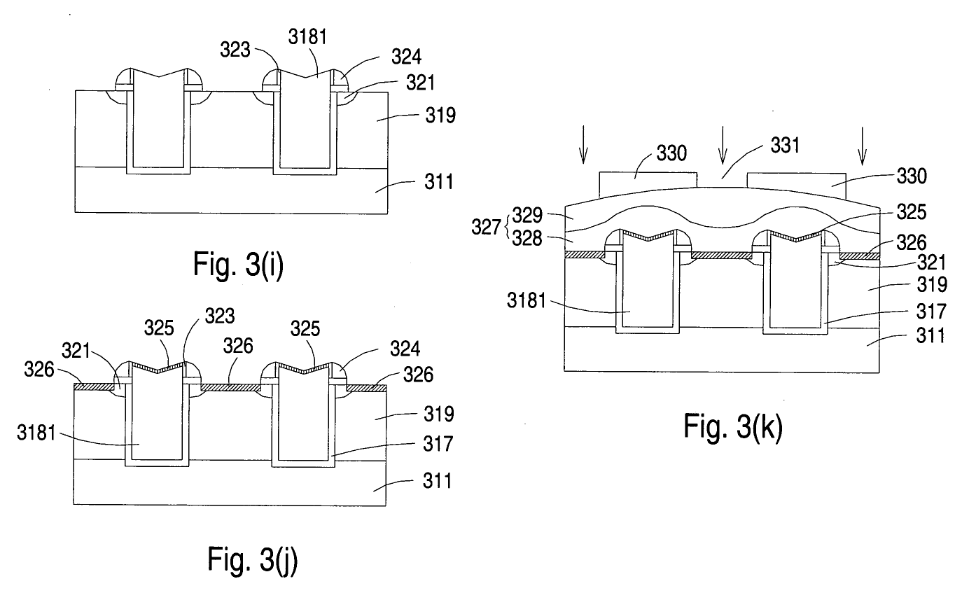

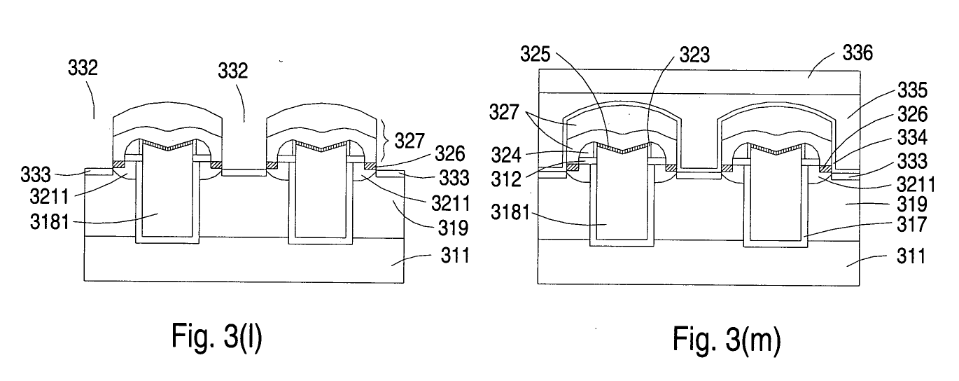

Please refer to FIGS. 3(a)-(m), which are schematic diagrams showing the process for fabricating the trench power semiconductor device according to a preferred embodiment of the present invention. In this embodiment, the trench power semiconductor device is preferably a trench power metal-oxide-semiconductor field effect transistor (trench power MOSFET) but not limited thereto, and the process comprises the following steps. Firstly, a substrate 311 is provided and a pad oxide layer 312, a first dielectric layer 313, and a mask oxide layer 314 are formed on the substrate 311 in order as shown in FIG. 3(a). In this embodiment, the substrate 311, the first dielectric layer 313, and the mask oxide layer 314 are preferably a silica substrate, a silicon nitride mask (mask SiN), and a Tetra Ethyl Ortho Silicate (TEOS), respectively, wherein the first dielectric layer 313 and the mask oxide layer 314 are preferably formed by chemical vapor deposition (CVD), but not limited thereto. The pad oxide layer 312 serves as a buffer to reduce the stress among the substrate 311, the first dielectric layer 313 and the mask oxide layer 314.

As shown in FIG. 3(b), photolithography and etching procedure are preformed subsequently to remove portion of the mask oxide layer 314, so as to define the trench opening 315 and expose portion of the first dielectric layer 313. The mask oxide layer 314 is provided as a mask to remove portion of the first dielectric layer 313, portion of the pad oxide layer 312, and portion of the substrate 311 via etching procedure such as isotropic etching in order to form a trench structure 316 (as shown in FIG. 3(c)). The mask oxide layer 314 is then removed and a sacrifice oxide layer (not shown) is formed through oxidation, such as thermal oxidation. The sacrifice oxide layer is removed afterwards. As shown in FIG. 3(d), a method such as thermal oxidation is performed to form a gate oxide layer 317 at the inner sidewall of the trench structure 316. Because the operation properties of the trench power MOSFET is affected by the thickness of the gate oxide layer 317, the thickness of the gate oxide layer 317 is controlled and regulated according to the requirement. After the formation of the gate oxide layer 317, a polysilicon layer 318 is deposited on the surface of the first dielectric layer 313 and fully deposited into the interior of trench structure 316, in other words, the trench structure 316 is covered by the polysilicon layer 318 as shown in FIG. 3(d).

As shown in FIG. 3(e), etching procedure such as dry etching is preferably applied to remove portion of the polysilicon layer 318 for forming the gate 3181 of the trench power MOSFET. Later, as shown in FIG. 3(f), the first dielectric layer 313 is removed to form the gate 3181 with a height higher than the trench structure 316 or the surface of the pad oxide layer 312. Body implantation procedure and body drive-in procedure are then processed onto the substrate 311 to form a body structure 319 within the substrate 311.

After body implantation and body drive-in procedures, a photoresist layer 320 is formed on the body structure 319 to define source photoresist by photolithography. Afterwards, source implantation procedure and source drive-in procedure are conducted to form a source 321 and then remove the photoresist layer 320. In this embodiment, the source 321 is preferably formed between the body structure 319 and the gate oxide layer 317.

Subsequently, deposition such as chemical vapor deposition is preferably applied to form an insulation layer 322 on top of the above-mentioned structure; meanwhile, an oxide layer 323 is naturally formed between the insulation layer 322 and the gate 3181 composed of polysilicon (as shown in FIG. 3(h)). Etching procedure such as dry etching is preferably utilized subsequently to remove portion of the insulation layer 322, portion of the pad oxide layer 312 and portion of the oxide layer 323, so as to form a sidewall structure 324 at two laterals of the gate 3181 protruded from the surface of the trench structure 316 and to expose portion of the source 321 and portion of the substrate 311, as shown in FIG. 3(i).

As shown in FIG. 3(j), salicidation procedure is conducted onto the above-mentioned structure to simultaneously form the first conductive layer 325 and 326 at the surface of the gate 3181 and portion structure of the source 321 and the substrate 311. In this embodiment, the first conductive layer 325 and 326 is preferably a low conductivity material, such as titanium silicide layer. Because the resistance of the titanium silicide layer is ⅕ of that of the polysilicon of the gate 3181, and the relationship between each gate 3181 shows in a parallel connection manner (not shown), the purpose for decreasing the net resistance of the gate 3181 can be achieved by the disposition of the titanium silicide layer. In this embodiment, due to the additional formation of the first dielectric layer 313 between the pad oxide layer 312 and the mask oxide layer 314, the gate 3181 with height higher than the surface of the pad oxide layer 312 can be obtained after the removal of the first dielectric layer 313. In addition, the isolation between the source 321 and the first conductive layer 325 on the surface of the gate 3181 can be further enhanced through the sidewall structure 324. Therefore, when the proposed trench power MOSFET of the present invention is processed at high frequency; the disposition of the first conductive layer 325 will not cause the poor isolation of the gate oxide layer 317 and thus short circuit between the gate 3181 and the source 321 can be further prevented.

As shown in FIG. 3(k), a second dielectric layer 327 is then formed on the above-mentioned structure by chemical vapor deposition, followed by forming a photoresist 330 on top of the second dielectric layer 327, and defining the contact region opening 331 by microlithography. In this embodiment, the second dielectric layer 327 preferably comprises two dielectric layers with different materials, wherein the applied layers are preferably non-doped-silicate-glass layer 328 (NSG layer) and borophospho-silicate-glass layer 329 (BPSG layer), but not limited thereto.

Afterwards, as shown in FIG. 3(l), portion of the second dielectric layer 327, portion of the first conductive layer 326, portion of the source 321, and portion of the body structure 319 are removed through the corresponding contact region opening 331, hence the source structure 3211 and the contact region 332 are defined, followed by the removal of the photoresist 330.

After the completion of the foregoing described procedures, implantation procedure is performed to form the contact plus structure 333 within the body structure 319 through the contact region 332, wherein the surface of the contact plus structure 333 is exposed through the contact region 332, as shown in FIG. 3(l). Moreover, a procedure such as sputtering process is preferably used to form the second conductive layer 334 on the surface of the structure shown in FIG. 3(l). In this embodiment, the second conductive layer 334 is preferably a titanium nitride layer (TiN layer), but not limited thereto. Later on, the contact metal layer 335 is deposited on the second conductive layer 334, wherein the contact metal layer 335 is preferably an aluminum-silicon-copper layer (AlSiCu layer), but not limited thereto. Furthermore, a protective layer 336 is formed on the contact metal layer 335 and photolithography and etching procedures are used to define the layouts (not shown) eventually, the trench power MOSFET as depicted in FIG. 3(m) is fabricated.

The trench power MOSFET according to a preferred embodiment of the present invention is shown in FIG. 3(m). The structure of transistor comprises: the substrate 311, the trench structure 316 (as shown in FIG. 3(c)), the pad oxide layer 312, the gate oxide layer 317, the gate 3181, the body structure 319, the oxide layer 323, the sidewall structure 324, the first conductive layer 325 and 326, the second dielectric layer 327, the contact plus structure 333, the second conductive layer 334, the source structure 3211, the contact metal layer 335, and the protective layer 336, but not limited thereto. The trench structure 316 is formed in the substrate 311, the gate oxide layer 317 is formed at the inner sidewall of the trench structure 316, and the gate 3181 is formed within the interior of the trench structure 316 and protruded from the surface of the trench structure 316. In addition, the sidewall structure 324 is formed at the laterals of the gate 3181 that protruded from the surface of the trench structure 316. The first conductive layer 325 and 326 is formed at the surface of the gate 3181 and the surface of partial source structure 3211. As regards the source structure 3211, it is formed within the substrate 311 and nearby the gate oxide layer 317.

In some embodiments, the gate 3181 is preferably a polysilicon layer, and the first conductive layer 325 and 326 is preferably a titanium silicide layer, but not limited thereto. In addition, the trench power MOSFET of the present invention further comprises a body structure 319 formed within substrate 311. Furthermore, the trench power MOSFET of the present invention can also comprise a dielectric layer 327 formed on the first conductive layer 325 and 326 and the sidewall structure 324.

In some other embodiments, the trench power MOSFET of the present invention can further comprise a contact plus structure 333 formed on the substrate 311 and a second conductive layer 334 formed on the dielectric layer 327 and the contact plus structure 333, but not limited thereto. Moreover, the trench power MOSFET of the present invention can also comprise a contact metal layer 335 and a protective layer 366 formed on the top of the second conductive layer 334, wherein the second conductive layer 334 is preferably but not limited to a titanium nitride layer (TiN layer).

In summary, the purpose of the present embodiment is to form an alternative first dielectric layer 313 between the pad oxide layer 312 and the mask oxide layer 314. Hence a gate 3181 with a height higher than the surface of the pad oxide layer 312 can be obtained after the removal of the first dielectric layer 313, and the source structure 3211 and the first conductive layer 325 formed at the surface of the gate 3181 can be isolated through the sidewall structure 324. When the trench power MOSFET of the present invention is processed at high frequency, the net resistance of the gate 3181 can be reduced by the first conductive layer 325, and thus the electrical properties of the trench power MOSFET can be elevated. Furthermore, through the isolation of the sidewall structure 324, the poor isolation of the gate oxide layer 317 with the disposition of the first conductive layer 325 can be avoided; therefore the voltage applied to the gate 3181 will not conduct to the source structure 3211 directly, and thus the possibility of short circuit between the gate 3181 and the source structure 3211 can also be prevented. In addition, the first conductive layer 326 formed at the source structure 3211 can also increase the contact area of source structure 3211.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A process for fabricating a trench power semiconductor device, comprising steps of:
(a) providing a substrate, forming a first dielectric layer on said substrate and removing portion of said first dielectric layer and portion of said substrate to form a trench structure;
(b) forming a gate oxide layer at inner sidewall of said trench structure;
(c) depositing a polysilicon layer to cover said trench structure and removing portion of said polysilicon layer to form a gate within said trench structure;
(d) removing said first dielectric layer for allowing portion of said gate to be protruded from the surface of said trench structure and forming a body structure within said substrate;
(e) forming a source between said body structure and said gate oxide layer;
(f) forming an insulation layer on said gate and said substrate;
(g) removing portion of said insulation layer to form a sidewall structure at laterals of said gate protruded from said trench structure and expose portion of said source and said substrate;
(h) forming a first conductive layer at the surface of said gate and the exposed portion of said source and said substrate;
(i) forming a second dielectric layer on said first conductive layer and said sidewall structure;
(j) removing portion of said second dielectric layer, portion of said first conductive layer and portion of said source to define a source structure and forming a contact region;
(k) forming a second conductive layer on said contact region and said second dielectric layer; and
(l) forming a contact metal layer on said second conductive layer.

2. The process according to claim 1 wherein said step (a) further comprises steps of:
(a1) providing said substrate and forming a pad oxide layer, said first dielectric layer and a mask oxide layer on said substrate in order;
(a2) removing portion of said mask oxide layer to form a trench opening;
(a3) removing portion of said first dielectric layer, portion of said pad oxide layer, and portion of said substrate by using said mask oxide layer as a mask to form said trench structure; and
(a4) removing said mask oxide layer.

3. The process according to claim 1 wherein said first dielectric layer is silicon nitride mask.

4. The process according to claim 1 wherein said body structure in said step (d) is formed by a body implantation procedure and a body drive-in procedure.

5. The process according to claim 1 wherein said step (e) further comprises steps of:
(e1) forming a photoresist layer on said body structure and defining source photoresist by photolithography; and
(e2) performing a source implantation procedure and a source drive-in procedure to form said source.

6. The process according to claim 1 wherein said step (h) is performed by a salicidation procedure.

7. The process according to claim 1 wherein said first conductive layer and said second conductive layer are a titanium silicide layer and a titanium nitride layer, respectively.

8. The process according to claim 1 wherein said second dielectric layer comprises a borophospho-silicate-glass layer and a non-doped-silicate-glass layer.

9. The process according to claim 1 wherein prior then said step (k) further comprises a step of forming a contact plus structure in said body structure and exposing said contact plus structure through said contact region.

10. The process according to claim 1 wherein after said step (l) further comprises a step (m) forming a protective layer on said contact metal layer.

11. The process according to claim 1 wherein said trench power semiconductor device is a trench power metal-oxide-semiconductor field effect transistor.

12. A trench power semiconductor device comprising:
a substrate;
at least a trench structure formed in said substrate;
a gate oxide layer formed at inner sidewall of said trench structure;
a gate formed within said trench structure and partially protruded from the surface of said trench structure;
a sidewall structure formed at laterals of said gate protruded from the surface of said trench structure;
a first conductive layer formed at least at the surface of said gate; and
a source structure formed within said substrate and nearby said gate oxide layer.

13. The trench power semiconductor device according to claim 12 wherein said gate is a polysilicon layer.

14. The trench power semiconductor device according to claim 12 wherein said first conductive layer is a titanium silicide layer and further formed at portion of said source structure.

15. The trench power semiconductor device according to claim 12 further comprising a body structure formed within said substrate.

16. The trench power semiconductor device according to claim 12 further comprising a dielectric layer formed on said first conductive layer and said sidewall structure.

17. The trench power semiconductor device according to claim 16 further comprising a contact plus structure formed on said substrate.

18. The trench power semiconductor device according to claim 17 further comprising a second conductive layer being a titanium nitride layer formed on said dielectric layer and said contact plus structure.

19. The trench power semiconductor device according to claim 18 further comprising a contact metal layer and a protective layer formed on said second conductive layer.

20. The trench power semiconductor device according to claim 12 being a trench power metal-oxide-semiconductor field effect transistor.
